(19) United States
(12) Patent Application Publication
(10) Pub. No.: US 2012/0198304 A1
(43) Pub. Date: Aug. 2, 2012

(54) INFORMATION REPRODUCTION APPARATUS AND INFORMATION REPRODUCTION METHOD

(75) Inventors: Yosuke KONDO, Fussa-shi (JP); Kenji Yoshida, Akishima-shi (JP)

(73) Assignee: Kabushiki Kaisha Toshiba, Tokyo (JP)

(21) Appl. No.: 13/338,496

(22) Filed: Dec. 28, 2011

(30) Foreign Application Priority Data
Jan. 31, 2011 (JP) 2011-018963

(51) Int. Cl. H03M 13/03; G06F 11/10

(52) U.S. Cl. 714/758; 714/E11.032

(57) ABSTRACT

According to one embodiment, an information reproduction apparatus includes a calculator, selector, and decoder. The calculator calculates parity-check passing ratios based on a check matrix of an LDPC code for code word candidates included in a reproduced signal. The selector selects one of the code word candidates based on the parity-check passing ratios calculated by the calculator. The decoder decodes the code word candidate selected by the selector by an iterative decoding process.

### CROSS-REFERENCE TO RELATED APPLICATIONS

This application is based upon and claims the benefit of priority from prior Japanese Patent Application No. 2011-018963, filed Jan. 31, 2011, the entire contents of which are incorporated herein by reference.

### FIELD

Embodiments described herein relate generally to an information reproduction apparatus and information reproduction method.

### BACKGROUND

In an information reproduction apparatus such as a hard disk device, it is required to detect the head position of a code word for each sector when user data stored in a storage medium is reproduced. The code word is configured by RLL-modulated user data and an ECC created from the user data. A sync mark written in the storage medium is utilized for detection of the head position of the code word. That is, the head position of the code word is detected by detecting the sync mark in each sector on the storage medium. An ECC code is not used for the sync mark, unlike the user data, and an error tolerant code is used to detect an error even if a one-bit error is present. Determination of whether data of a preset length read from the storage medium is a sync mark or not is made by extracting a data string of the same bit, length as that of the sync mark from data read from the storage medium and comparing the data with a sync mark pattern. If both data items coincide in a preset number of bits or more bits, the data string can be determined as a sync mark. Determination based on a Euclidean distance can be used as determination of coincidence with the sync mark pattern in addition to the above determination based on a Hamming distance.

Recently, in an information reproduction apparatus such as a hard disk device, it is required to record data with high density. Therefore, a bit error tends to occur and a sync mark that is a non-ECC code may not be detected. If a sync mark is not detected, the user data cannot be reproduced. Conventionally, in order to cope with a case wherein the sync mark is not detected, the technique for estimating the head position of sector data and determining the head position of sector data according to whether or not reliability information derived based on the estimated value satisfies a threshold value is proposed.

The conventional information reproduction apparatus must repeatedly estimate the head position of sector data until reliability information satisfies the threshold value and there occurs a possibility that the head position of the code word cannot be determined.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary block diagram showing the typical configuration of an information reproduction apparatus according to a first embodiment.

FIG. 2 is an exemplary diagram showing one example of detection of a sync mark.

FIG. 3 is an exemplary block diagram showing the typical configuration of reproducing data read from a storage medium in a read/write block 32 shown in FIG. 1.

FIG. 4 is an exemplary block diagram of a code word head position detector 510 shown in FIG. 3.

FIG. 5 is an exemplary diagram showing a parity check in an LDPC-decoding process according to the first embodiment.

FIG. 6 is an exemplary diagram showing detection of the head position of a code word by using the parity-check passing ratio by a determination module 604 shown in FIG. 3.

FIG. 7 is an exemplary diagram showing one example of a format of split sectors according to a second embodiment.

### DETAILED DESCRIPTION

Various embodiments will be described hereinafter with reference to the accompanying drawings.

In general, according to one embodiment, an information reproduction apparatus includes a calculator, selector, and decoder. The calculator calculates parity-check passing ratios based on a check matrix of an LDPC code for code word candidates included in a reproduced signal. The selector selects one of the code word candidates based on the parity-check passing ratios calculated by the calculator. The decoder decodes the code word candidate selected by the selector by an iterative decoding process.

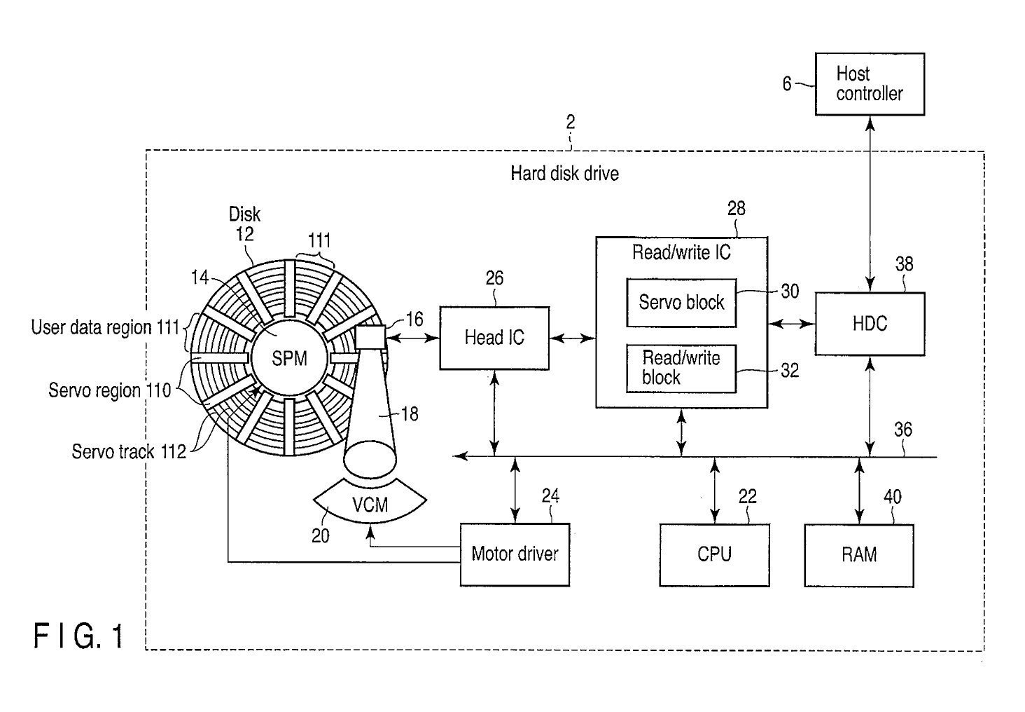

FIG. 1 is a block diagram showing the typical configuration of a hard disk drive 2 used as one example of an information reproduction apparatus according to a first embodiment. The hard disk drive 2 is a recording device that writes data (including a code word and sync mark) on the recording surface of a recording medium 12 or reads data from the recording surface in response to a request from a host controller 6 used as a host system and mainly includes a disk 12, head 16 and read/write block 32.

The disk 12 includes several data regions from which data is read by means of the head 16. For example, the disk includes a user data region 111 in which user data supplied from a host (not shown) is written and a servo region 110 in which servo data used to specify the position of the head 16 and move the head 16 to a target position is written.

The read/write block 32 subjects data written in the disk 12 or data read from the disk 12 by means of the head 16 to several signal processes. For example, the processes of coding data to be written in the disk 12, decoding data read from the disk 12 and correcting an error of data read at the decoding time are performed by means of the read/write block 32.

A spindle motor (SPM) 14 is connected to a motor driver 24 to fix the disk 12. The spindle motor (SPM) 14 rotates the disk 12 at a constant speed. The rotating operation is performed by the motor driver 24 under control of a CPU 22 connected thereto via a CPU bus 36.

A voice coil motor (VCM) 20 is driven by the motor driver 24 under control of the CPU 22 connected thereto via the CPU bus 36. The VCM 20 is connected to an actuator 18 that fixes the head 16. The head 16 is moved to a target track on the disk 12 by driving the VCM 20. The target track is controlled by the CPU 22 and the control operation is performed to set the track in a target range.

A head IC 26 amplifies an analog signal read from the disk 12 by the head 16. The analog signal is supplied to a read/write IC 28. The process described above is performed by means of the read/write block 32 included in the read/write IC 28 and the processed signal is supplied to the host controller 6 connected via a hard disk controller (HDC) 38.

To the CPU bus 36, the motor driver 24, head IC 26, read/write IC 28, HDC 38 and RAM 40 are connected. In the RAM 40, for example, various variables used by the CPU 22 are stored. A part of the storage region of the RAM 40 is used as a work area of the CPU 22.

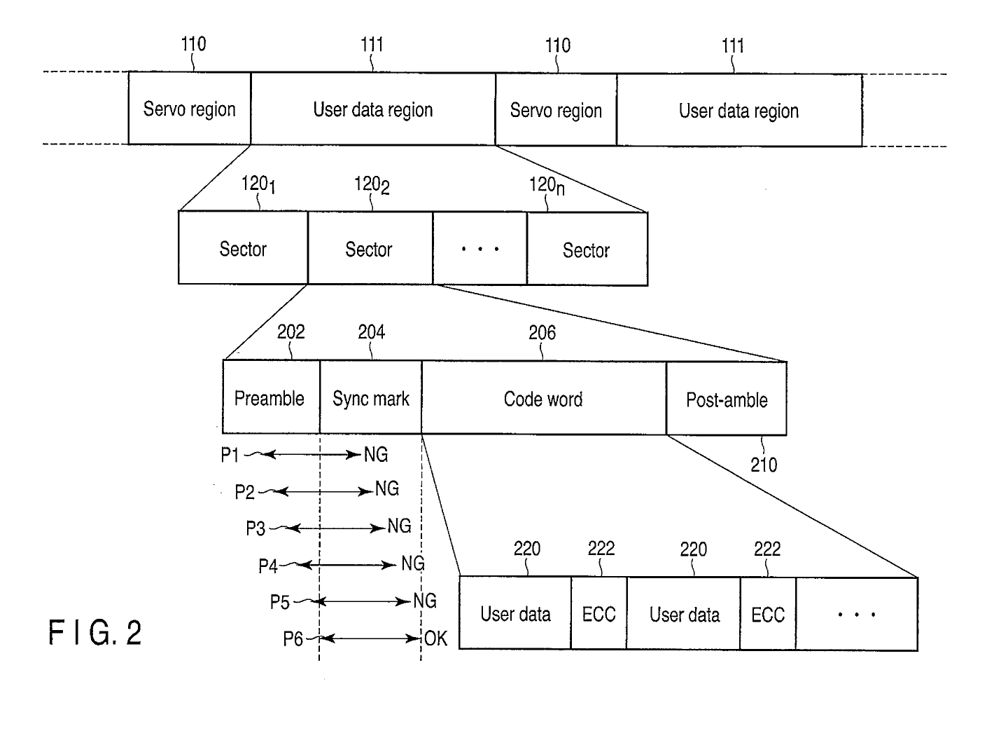

The data format of the disk 12 is explained with reference to FIG. 2. Data obtained by developing data recorded on the disk 12 along a servo track 112 shown in FIG. 1 on a straight line is shown in FIG. 2. A plurality of sectors 120₁ to 120ₙ are recorded in a user data region 111 between two servo regions 110. Each sector includes a preamble 202, sync mark 204, code word 206 and post-amble 210 and has fixed data length. The code word 206 is configured by user data 220 and ECC 222. In an information reproduction apparatus using a low-density parity-check (LDPC) code, as shown in FIG. 2, a code word is often configured by dispersedly arranging error correction codes (ECCs) 222 in run-length limited (RLL)-modulated user data items 220. Since the length of the user data region 111 in the circumference direction is different in the inner periphery and outer periphery of the disk 12, the number n of sectors included in one user data region 111 is different in the inner periphery and outer periphery of the disk 12.

For convenience of the explanation, an example in which an integral number of sectors are recorded in the user data region 111 is shown in FIG. 2. However, in practice, the data length of the user data region 111 is not set to an integral multiple of the data length of the sector, and a fraction may occur and one sector may be divided into two portions that are respectively recorded in two user data regions with the servo region 110 sandwiched therebetween. Such sectors are called split sectors. The data format of the split sector is described later.

In the preamble 202, a sync signal of a PLL circuit used when data read from the disk 12 is reproduced (that is hereinafter referred to as “at the reproduction time”) is included. As described before, in the sync mark 204, a code for detecting the head position of a code word at the reproduction time is included. User data 220 is data from a host system such as a personal computer, for example, and has the fixed bit length of 512 bytes.

The ECC 222 is data for error correction and the correction ability thereof can be enhanced by increasing the bit length. The ECC 222 is recorded as redundant bits at the write time by the read/write block 32 and used to correct an error of data at the read time. The post-amble 210 is additionally provided to terminate maximum likelihood (ML) determination of partial response maximum likelihood (PRML) irrespective of this application.

Thus, since the sync mark 204 is arranged before the code word 206 in each sector in the user data region 111, it is understood that the head position of the code word 206 can be detected by detecting the sync mark 204.

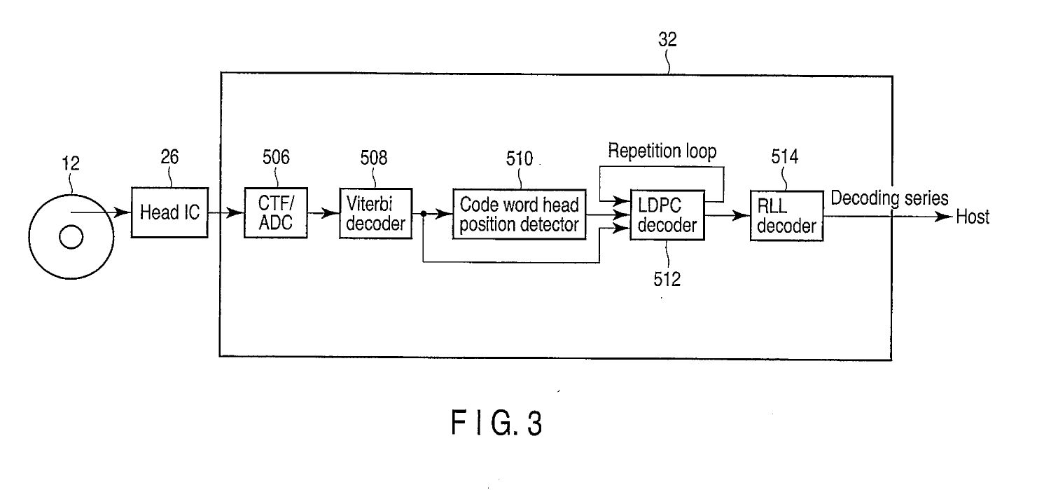

FIG. 3 is a block diagram showing the typical function when data read from the disk 12 in the first embodiment is reproduced. Data read from the disk 12 is amplified by the head IC 26 and the amplified analog signal is input to a continuous time filter (CTF)/analog-digital converter (ADC) 506. The CTF/ADC 506 converts an analog signal to a digital signal by waveform-equalizing a signal input from the head IC 26. A signal output from the CTF/ADC 506 is subjected to a soft-decision error-correction decoding process by a Viterbi decoder (maximum likelihood decoder) 508 that is one type of a convolution decoder. As the Viterbi decoder in the record/reproduction system using an LDPC code, a Viterbi decoder that makes binary hard decision for a iterative process of an LDPC-decoding process is not used but a soft-decision Viterbi decoder that outputs “0”-like data or “1”-like data is used. Therefore, a Viterbi decoder 508 outputs a soft decision value. A soft decision value output from the Viterbi decoder 508 is input to an LDPC decoder 512 and is made hard-decision (determined to be 0 or 1) with reference to a certain threshold value and then input to a code word head position detector 510.

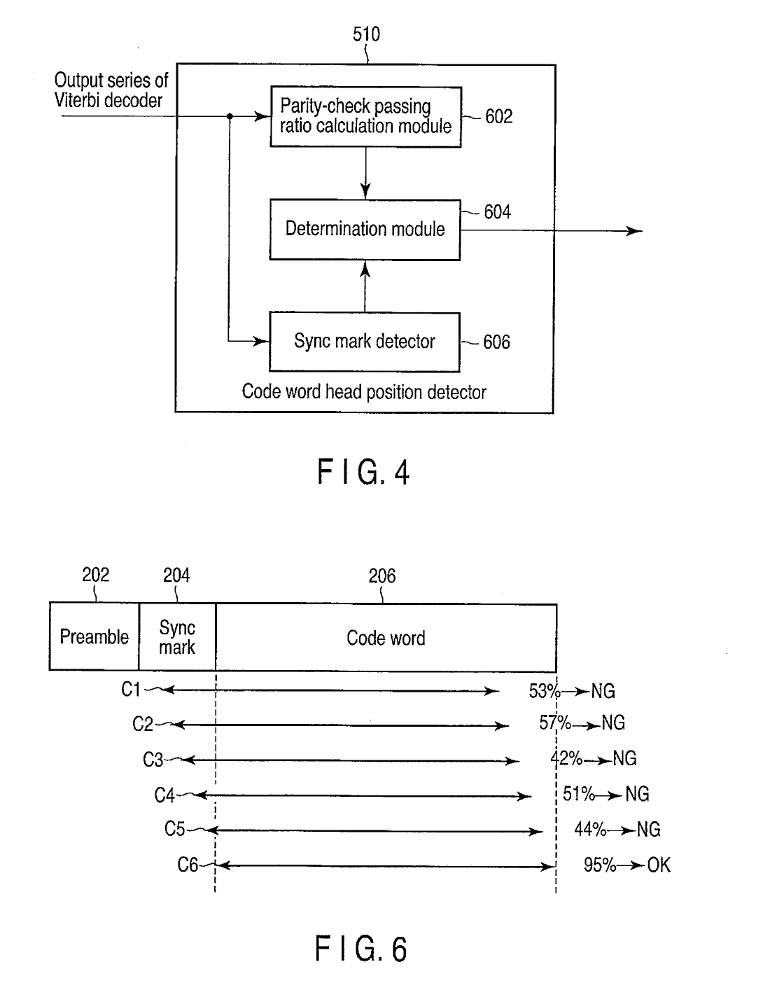

Though details will be explained later with reference to FIG. 4, the code word head position detector 510 detects a sync mark, detects a code word based on the parity-check passing ratio by using an check matrix of low-density parity checks (also called LDPC) and detects the head position of the code word based on both of the detection results.

Information of the head position of the code word detected by the code word head position detector 510 and a soft decision value of a to-be-decoded sequence obtained by the Viterbi decoder 508 are input to the LDPC decoder 512 that in turn performs an LDPC-decoding process that is one type of a iterative error-correction decoding process. If the LDPC-decoding process is successfully performed, the LDPC decoder 512 outputs an error-corrected code word 206. The code word 206 is input to an RLL demodulator 514 and subjected to an RLL demodulation process and data recorded on the disk 12 is reproduced. The reproduction signal demodulated by the RLL demodulator 514 is supplied to a host (not shown) via an ATA (or IDE) bus, for example. As described above, data read from the disk 12 is decoded and data is reproduced.

Next, the code word head position detector 510 of the first embodiment is explained in detail with reference to FIG. 4.

FIG. 4 is a block diagram for illustrating the function of the code word head position detector 510 shown in FIG. 3. The code word head position detector 510 includes a parity-check passing ratio calculation module 602, determination module 604 and sync mark detector 606.

An output sequence decoded by the Viterbi decoder 508 is input to the parity-check passing ratio calculation module 602 and sync mark detector 606. The detection results detected by the parity-check passing ratio calculation module 602 and sync mark detector 606 are input to the determination module 604. The validity of the detection result by the sync mark detector 606 is verified based on the parity-check passing ratio. The head position of the code word 206 that is the detection result of a sync mark verified by the determination module 604 is supplied to the LDPC decoder 512 shown in FIG. 3.

The detection operation of the sync mark detector 606 is explained with reference to FIG. 2. When detecting a preamble 202, the sync mark detector 606 sequentially extracts data strings Pi (I=1, 2, . . . ) of the same bit length as that of the sync mark from data read from the disk 12. That is, data string Pi is a candidate of a sync mark. Each time candidate Pi is extracted, the sync mark detector 606 compares candidate Pi with a sync mark pattern to determine whether both data items coincide with each other in a preset number of bits or more bits. When candidate Pi (P6 in the example of FIG. 2) that coincides with the sync mark pattern in a preset number of bits or more bits is detected, the sync mark detector 606 terminates the process of extracting a sync mark candidate from data read from the disk 12 and detecting the sync mark. As the determination for coincidence between both data items, determination based on a Euclidean distance may be used in addition to the above determination based on a Hamming distance.

In the above case, the determination for coincidence between the candidate and the sync mark pattern is performed each time candidate Pi is input and is continuously performed until the candidate coincides with the sync mark pattern in a preset number of bits or more bits. However, instead of this, it is possible to previously input a preset number of candidates Pi and detect a candidate among the preset number of candidates that coincides with the sync mark pattern with the highest degree.

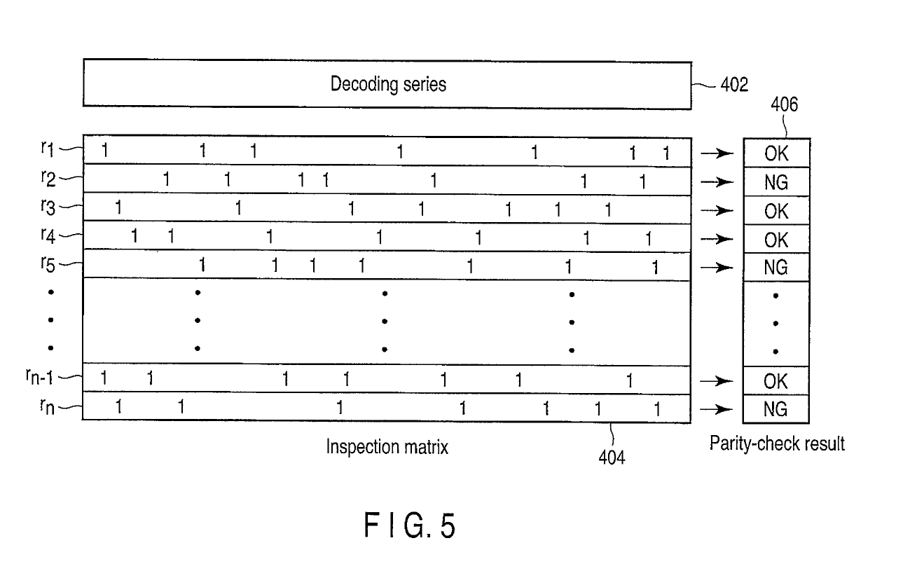

The parity-check passing ratio calculation method performed by the parity-check passing ratio calculation module 602 is explained with reference to FIG. 5.

FIG. 5 shows the state of a parity check in the decoding process in the LDPC decoder 512. A decoding sequence 402 is a part of an output sequence supplied from the Viterbi decoder 508, the length thereof is equal to the total length of the user data 220 and ECC 222 and is made a hard-decision sequence of 0s or 1s. Each of r₁ to rₙ corresponds to each row of an n-row parity-check matrix 404. The parity-check matrix 404 is configured by elements of “1” or “0”. The check matrix 404 uses a hard-decision result in a position of a decoding sequence corresponding to a position in which “1” is set to perform a parity check in the row direction and determine whether the parity equation is satisfied or not. If the hard-decision result is incorrect, the parity-check result will become NG with a strong possibility. If the decoding sequence has no error, all of the parity-check results become OK. If errors occur, but the number of errors is suppressed in a correctable range, the number of parity-check results that become OK gradually increases while the LDPC-decoding process is iteratively performed, and all of the parity-check results become OK when no error is finally detected. The parity-check passing ratio is the ratio of the number of rows in which the parity-check results are determined as OK to the total number of rows in the check matrix. If the decoding sequence is a code word itself and the number of errors is less than the number of errors that can be corrected, all of the parity-check results become OK while the LDPC-decoding process is iteratively performed, that is, the parity-check passing ratio becomes 1.

The LDPC decoder 512 subjects an output of the Viterbi decoder 508 to an LDPC-decoding process. The parity check is performed each time the LDPC-decoding process is performed once. When no error is detected or if errors are detected but the number of errors is less than the number of errors that can be corrected, the LDPC-decoding process is correctly terminated. If the number of errors is not less than the number of errors that can be corrected, the LDPC-decoding process is iteratively performed. The maximum number of iterative operations is limited.

The parity-check passing ratio calculation module 602 receives a parity-check result from the LDPC decoder and calculates a parity-check passing ratio as described above.

For example, when the total number of rows of the parity-check matrix 404 is n and the number of rows in which the parity-check results 406 are determined OK is k, the parity-check passing ratio can be derived by 100×(k/n) (%).

A method for detecting the code word 206 by using the parity-check passing ratio is explained with reference to FIG. 6. For convenience of the explanation, portions that are the same as those of FIG. 2 are omitted in FIG. 6.

When detecting the preamble 202, the LDPC decoder 512 sequentially extracts data strings Cj (j=1, 2, . . . ) of the same bit length as that of the code word from the decoding sequence. That is, the data string Cj is a candidate of the code word. Each time the candidate Cj is extracted, the LDPC decoder 512 subjects the candidate Cj to an LDPC-decoding process and performs the parity check. The passing ratio may be calculated for each LDPC-decoding process or may be calculated once after a preset number of LDPC-decoding processes are performed or the LDPC-decoding process is iteratively performed until no error occurs. In the actual product, modes are provided and the above operations can be selected. The parity-check result for each row of the check matrix is supplied to the parity-check passing ratio calculation module 602. The parity-check passing ratio calculation module 602 calculates a parity-check passing ratio for each candidate Cj of the code word. In the example of FIG. 6, it is supposed that the parity-check passing ratios for respective candidates Cj (j=1 to 6) of the code word are 53%, 57%, 42%, 51%, 44% and 95%.

The parity-check passing ratio calculation module 602 determines candidate Cj that can be regarded as the code word 206 based on the parity-check passing ratio for each candidate Cj of the code word. For example, three determination methods are explained as a concrete example of the determination method.

In the first determination method, the parity-check passing ratio calculation module 602 calculates a parity-check passing ratio each time the LDPC decoder 512 extracts data string Cj (j=1, 2, . . . ) of the same bit length as that of the code word from the decoding sequence. When the parity-check passing ratio of candidate C1 is not less than a threshold value, the circuit detects candidate C1 as the code word. When the parity-check passing ratio of candidate C1 is less than the threshold value, the parity-check passing ratio calculation module 602 calculates a parity-check passing ratio of next candidate C2 and determines whether or not the ratio exceeds the threshold value. In this example, if it is supposed that the threshold value is set to 90%, the operation of calculating the parity-check passing ratio and comparing the result with the threshold value is repeatedly performed until candidate C6 is reached. Then, candidate C6 whose parity-check passing ratio is 95% is determined as the code word. It is supposed that the threshold value can be freely determined according to hardware by the user.

In the second determination method, unlike the first determination method in which calculation and comparison are sequentially performed for each input of candidate Cj, a preset number of candidates Cj are previously input and parity-check passing ratios of all of the candidates are derived. When only one parity-check passing ratio among the above parity-check passing ratios exceeds the threshold value, the code word 206 is determined based on the candidate. Specifically, for example, if the threshold value is set to 90%, only the parity-check passing ratio (95%) of candidate C6 exceeds the threshold value and candidate C6 is determined as the code word 206 as shown in FIG. 6.

In the third determination method, like the second determination method, a preset number of candidates Cj are previously input and parity-check passing ratios of all of the candidates are derived. A candidate whose parity-check passing ratio becomes a maximum value among the above parity-check passing ratios is determined as a code word. Specifically, for example, since the parity-check passing ratio (95%) of candidate C6 has a maximum value among the six parity-check passing ratios as shown in FIG. 6, the code word 206 is determined based on the parity-check passing ratio of candidate C6.

As described above, the parity-check passing ratio calculation module 602 determines the code word 206 based on the parity-check passing ratio of each candidate Cj of the code word, but the determination method is not limited to the above three methods and various other methods that can provide the same effect may be used.

With reference to FIG. 4, the code word head position detector 510 of the first embodiment is more concretely explained.

As described above, the determination module 604 determines the head position of a code word based on the code word 206 determined by the parity-check passing ratio calculation module 602 and the detection result of a sync mark detected by the sync mark detector 606.

For example, two determination methods as a concrete example of the determination method of the head position of the code word by the determination module 604 are explained.

In the first determination method, when the head position of a code word 206 determined by the parity-check passing ratio calculation module 602 coincides with the end position of a sync mark detected by the sync mark detector 606, the determination module 604 determines that the sync mark 204 is detected and the head position of the code word is specified. If the head position of a code word 206 determined by the parity-check passing ratio calculation module 602 does not coincide with the end position of a sync mark detected by the sync mark detector 606, the head position of the code word is not detected on the assumption that one of the detection results contains an error.

In the second determination method, when an operation result obtained by performing a preset operation process for the parity-check passing ratio calculated by the parity-check passing ratio calculation module 602 and the sync mark detection precision of the sync mark detector 606 (indicating the number of bits in which the sync mark pattern and the candidate (refer to FIG. 2) of the sync mark coincide with each other) exceeds a threshold value, it is determined that the detection result of the sync mark detector 606 is correct, the sync mark 204 is detected and the head position of the code word is specified.

Various other methods that provide the same effect based on signals obtained from the parity-check passing ratio calculation module 602 and the conventional sync mark detector 606 may be used in addition to the above two determination methods.

As described above, the code word head position detector 510 of the first embodiment includes the sync mark detector 606 and parity-check passing ratio calculation module 602.

The sync mark detector 606 is configured to detect a sync mark candidate that coincides with a sync mark pattern to the highest degree by comparing the sync mark candidate with the sync mark pattern.

The parity-check passing ratio calculation module 602 is configured to derive a code word candidate that is regarded as a code word based on the parity-check passing ratio when the code word candidate is LDPC-decoded and the head position of the code word is specified based on the outputs of the both circuits. Therefore, even if the recording density increases and a detection error of the sync mark occurs, the head position of the code word can be specified with high precision. Further, since the sync mark detection precision can be increased, the bit length of the sync mark can be reduced to increase the recording density when the detection precision is kept at the conventional detection precision.

A modification of the first embodiment is explained below.

For example, in the above embodiment, the parity-check passing ratio calculation module 602 always calculates the parity-check passing ratio, but can be configured to calculate the parity-check passing ratio only when a certain condition is satisfied. For example, when sync mark detection by the sync mark detector 606 results in failure, sync mark detection by the sync mark detector 606 is retried and the code word 206 may be detected based on the parity-check passing ratio by the parity-check passing ratio calculation module 602 only at the retry time. Alternatively, when sync mark detection by the sync mark detector 606 results in failure, the head position of the code word 206 may be detected only by means of the parity-check passing ratio calculation module 602 without retrying sync mark detection by the sync mark detector 606.

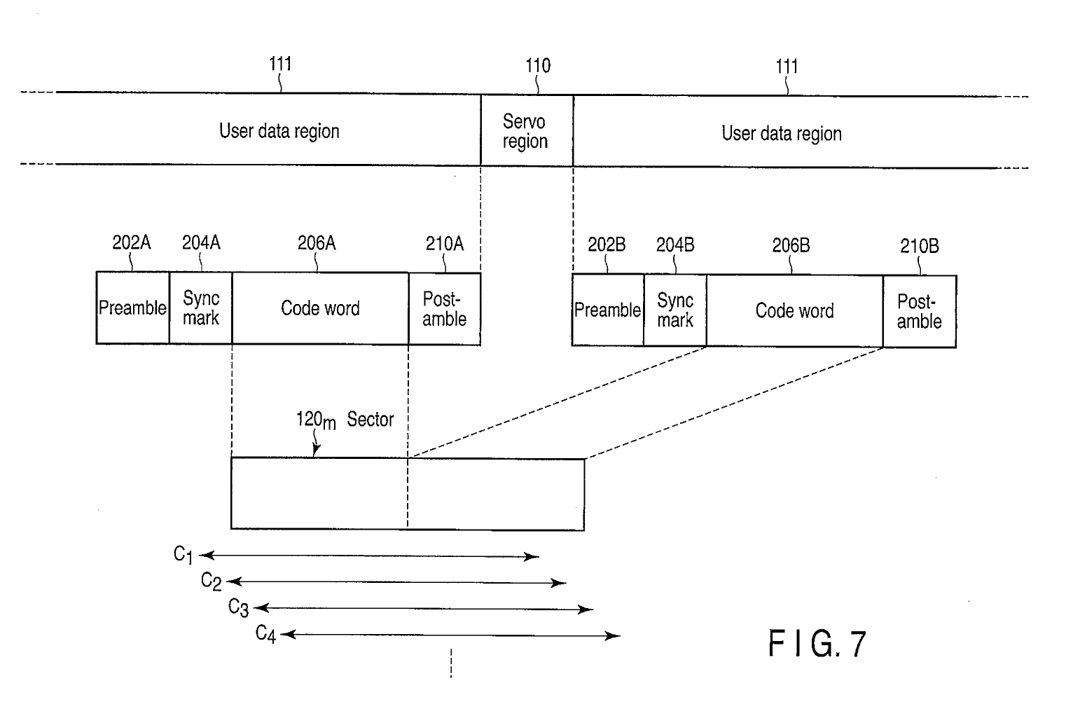

Next, the method of detecting the head position of the code word when the final sector of the user data region 111 does not fit into the user data region 111 and extends to a succeeding user data region 111 with the servo region 110 sandwiched therebetween, that is, in the case of split sectors is explained with reference to FIG. 7.

For example, as shown in FIG. 7, the final sector 120ₘ in the user data region 111 is divided into two split sectors by the servo region 110. In the respective split sectors, preambles 202A, 202B, sync marks 204A, 204B, code words 206A, 206B and post-ambles 210A, 210B are recorded. Therefore, the sync mark detector 606 shown in FIG. 4 detects the sync marks 204A, 204B in the respective split sectors.

When the parity-check passing ratio is used to detect a code word, only the code word of one whole sector can be detected. Therefore, in the split sectors, the sync mark detection precision can be increased by determining detection of the two sync marks of the sync marks 204A and 204B together with the parity-check passing ratio.

Next, a second embodiment is explained. The explanation for the same configurations and functions as those of the first embodiment is omitted.

In the first embodiment, specification of the head position of the code word by the parity-check passing ratio calculation module 602 is to verify or compensate for the detection result of the sync mark 204 by the sync mark detector 606. However, the head position of the code word 206 can be specified only by means of the parity-check passing ratio calculation module 602 without detecting the sync mark 204 by means of the sync mark detector 606. In this case, it is unnecessary to record the sync mark 204 in relation to the format of sector data shown in FIG. 2 and FIG. 7. It is supposed that recording or non-recording of the sync mark can be freely set by the user, according to the hardware.

In the second embodiment, a method for detecting the head position of the code word 206 when the sync mark 204 is not recorded on a disk 12 is provided. That is, a code word head position detector 510 of the second embodiment is configured only by the parity-check passing ratio calculation module 602 of the first embodiment and is used to determine candidate Cj that can be regarded as a code word 206 based on the parity-check passing ratio of each candidate Cj of the code word and detect the head position of the candidate.

Next, a case wherein the sector is divided as shown in FIG. 7 is explained. In the case of split sectors, a sync mark may be recorded in at least one split sector. In this case, in the split sector in which no sync mark is recorded, the head position of the code word 206 can be specified only by means of the parity-check passing ratio calculation module 602, like the first embodiment.

If the sector is divided and no sync mark is recorded in all of the split sectors, determination by the parity-check passing ratio calculation module 602 for code word candidates of the respective split sectors is made. An example of FIG. 7 is explained. If none of the sync marks 204A and 204B is recorded, the head positions of the code words 206A and 206B are derived based on the parity-check passing ratios. If five candidates of the head position of the code word 206A are provided and five candidates of the head position of the code word 206B are also provided, parity-check passing ratios are calculated for code word candidates of 5×5=25 and one of the three determination methods for the code word head position explained in the first embodiment is used for the calculation result.

The head position of the code word can be detected based on a signal sequence read from a disk on which no sync mark is recorded by performing the second embodiment. Since the sync mark is not recorded, the recording density can be increased.

Further, in the second embodiment, none of the sync marks is recorded, but it is possible to previously determine sectors in which sync marks are recorded and sectors in which no sync marks are recorded when, for example, the sector is divided into plural split sectors. As a result, head position candidates can suppress an increase in the number of combination patterns of the head positions due to an increase in the split number.

This invention is not limited to the above embodiments as they are and can be embodied by modifying the constituents without departing from the gist thereof at the embodying stage. Further, various inventions can be made by adequately combining a plurality of constituents disclosed in the above embodiments. For example, several constituents may be omitted from all of the constituents disclosed in the embodiments. In addition, constituents disclosed in the different embodiments may be adequately combined. In the embodiment, the hard disk drive is explained, but this invention can be applied to an information reproduction apparatus using an optical disk.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information reproduction apparatus comprising:
a calculator configured to calculate parity-check passing ratios based on a check matrix of an LDPC code for code word candidates included in a reproduced signal;
a selector configured to select one of the code word candidates based on the parity-check passing ratios calculated by the calculator; and
a decoder configured to decode the code word candidate selected by the selector by an iterative decoding process.

2. The apparatus of claim 1, wherein the selector is further configured to select a code word candidate having a parity-check passing ratio not less than a threshold value or a code word candidate having a maximum one of the parity-check passing ratios.

3. The apparatus of claim 1, further comprising a detector configured to detect a sync mark pattern included in the reproduced signal, wherein the selector is configured to select one of the code word candidates based on the sync mark pattern detected by the detector and the parity-check passing ratios calculated by the calculator.

4. The apparatus of claim 3, wherein the calculator is configured to calculate the parity-check passing ratios when the sync mark pattern is not detected by the detector.

5. An information reproduction method comprising:
calculating parity-check passing ratios based on a check matrix of LDPC code for code word candidates included in a reproduced signal;
selecting one of the code word candidates based on the calculated parity-check passing ratios; and
decoding the selected code word candidate by an iterative decoding process.

6. The method of claim 5, wherein the selecting comprises selecting a code word candidate having a parity-check passing ratio not less than a threshold value or a code word candidate having a maximum one of the parity-check passing ratios.

7. The method of claim 5, further comprising detecting a sync mark pattern included in the reproduced signal, wherein the selecting comprises selecting one of the code word candidates based on the detected sync mark pattern and the calculated parity-check passing ratios.

8. The method of claim 7, wherein the calculating comprises calculating the parity-check passing ratios when the sync mark pattern is not detected.

9. An information reproduction apparatus comprising:
a recording medium configured to store a code word for each sync mark non-recording sector;
a head configured to read a signal from the recording medium; and
an information reproduction module configured to process the signal read from the recording medium via the head and to reproduce the code word recorded on the recording medium, wherein the information reproduction module comprises:
a calculator configured to calculate parity-check passing ratios based on a check matrix of an LDPC code for code word candidates included in the signal read from the recording medium;
a selector configured to select one of the code word candidates based on the parity-check passing ratios calculated by the calculator; and
a decoder configured to decode the code word candidate selected by the selector by an iterative decoding process.

10. The apparatus of claim 9, wherein the selector is further configured to select a code word candidate having a parity-check passing ratio not less than a threshold value or a code word candidate having a maximum one of the parity-check passing ratios.

11. The apparatus of claim 9, further comprising a detector configured to detect a sync mark pattern included in the signal read from the recording medium, wherein the selector is configured to select one of the code word candidates based on the sync mark pattern detected by the detector and the parity-check passing ratios calculated by the calculator.

12. The apparatus of claim 11, wherein the calculator is configured to calculate the parity-check passing ratios when the sync mark pattern is not detected by the detector.
